(19) United States
(12) Patent Application Publication
(10) Pub. No.: US 2007/0247185 A1
(43) Pub. Date: Oct. 25, 2007

(54) Memory system with dynamic termination

(76) Inventors: Hideo Oie, Folsom, CA (US); Hany Fahmy, Elk Grove, CA (US); Christopher Cox, Placerville, CA (US); George Vergis, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/396,277

(22) Filed: Mar. 30, 2006

(51) Int. Cl. H03K 19/003

(52) U.S. Cl. 326/30

(57) ABSTRACT

The termination impedance of a memory agent may be selected dynamically. A transmission line may be simultaneously terminated with a first impedance at first memory agent and a different impedance at a second memory agent. A memory agent may have a terminator with at least two termination values and logic to dynamically select the termination values. Other embodiments are described and claimed.

### BACKGROUND

FIG. 1 illustrates a prior art functional diagram for a memory system with an on-motherboard termination scheme. The system of FIG. 1 includes a memory controller 10, Dynamic Random Access Memory (DRAM) modules 12 and 14, and a termination resistance 18 installed on the motherboard. A transmission bus 16 couples the memory controller 10 with the DRAMs 12 and 14. The DRAM module 12 is in active mode (i.e. it is currently being read from or written to by the memory controller 10); the other DRAM module 14 is in inactive mode. The active DRAM 12 receives signals from memory controller 10 through bus 16 and the module is set at low impedance (Lo-Z) to receive the signal. No signals are received at the inactive DRAM 14; so the inactive DRAM is set at high impedance (Hi-Z). The signal from the bus that reaches the motherboard termination impedance 18 is absorbed by it and hence is not reflected back. However, a portion of the signal received by the inactive DRAM 14 is reflected back to the bus due to lack of proper termination impedance at the end of the signal path in 14. This reflected signal propagates along the bus and reaches the active DRAM 12, thus adding noise to the signal received at DRAM 12. On-motherboard termination schemes have been used in Double Data Rate Synchronous Dynamic RAM (DDR SDRAM) memory technology.

FIG. 2 illustrates another prior art termination scheme where a termination resistance is embedded in a memory module itself. Such a termination scheme is called On-Die termination (ODT) and has been used in Double Data Rate 2 Synchronous Dynamic RAM (DDR2 SDRAM) technology. The system of FIG. 2 includes a memory controller 10, an SDRAM 12 that is in active mode, an SDRAM 14 that is in inactive mode, and termination impedance 20 installed in the memory module itself. The termination impedance 20 is switched on or off depending on the state of the memory module. When the memory module is in active mode (read or write mode), the termination impedance is switched off. When in inactive mode, this impedance is turned on to ensure effective termination of the signals in the inactive SDRAM, thereby resulting in no signal reflection from the inactive SDRAM. FIG. 2 shows that the termination impedance of 14 in inactive mode is switched on, thereby ensuring no signal reflection. This results in better signal quality as compared to the mother board termination scheme of FIG. 1 and also eliminates some of the wring in the motherboard, thereby facilitating system design and making the memory subsystem layout more efficient.

FIG. 3 illustrates the ODT termination scheme for DDR2 SDRAM in more detail. The system of FIG. 3 includes a DDR2 SDRAM memory module 30 coupled to a transmission bus 34. The input from the bus is received by an input buffer 38, the output of which is connected to an ODT terminator 32. The output of terminator 32 is connected to the DQ pin 54 of the SDRAM. The ODT 32 includes a pair of impedances 40 (each having value 2Z₁) connected between the output of 38 and a set of termination points (V_{DDQ} and V_{SSQ}) through a pair of switches 44. Note that 44 includes two switches, which are always turned on or off simultaneously. The ODT 32 also includes another pair of impedances 42 (each having a value 2Z₂) connected to the supply through a pair of switches 46. Switches 44 and 46 are controlled by an ODT controller 50, which in turn gets the required control values from an ODT pin 52. When either 44 or 46 are turned on, the SDRAM is terminated with a certain impedance value and this condition is termed as ODT “ON”. When switches 44 are turned on, the SDRAM is terminated with an impedance of Z₁. When switches 46 are turned on, the termination impedance is Z₂. When both 44 and 46 are turned off, the ODT is in an “OFF” state. Thus, in ODT OFF state, signals from the output of 38 are not terminated by the ODT 32 and is transmitted to the DQ pin 54 of the SDRAM.

FIG. 4 illustrates a prior art control scheme for ODT used in DDR2 SDRAM. Selection between switches 44 and 46 of FIG. 3 is determined by two bits (A₆ and A₂) of an Extended Mode Register Set (EMRS) that is input to the ODT 32 via the ODT pin 52. The two bits can be used to select “ODT not selected”, “ODT selected (75Ω)”, “ODT selected (150Ω)”, or “ODT selected (50Ω)”. Once the impedance value of the ODT is set, the setting is retained until another setting is entered or the power is turned off. However, in DDR2 technology, the ODT termination impedance value change requires an idle bus time. Also, once a termination impedance value (75Ω, 150Ω or 50Ω) is selected for an ODT ON state, the termination value remains same whenever the ODT is set to ON. Thus, in normal operation, the ODT can only enable or disable the termination, and not change the termination impedance value while being ON, except when the settings are changed in the extended mode register.

FIG. 5 illustrates the operation of a prior art memory system having ODT, used in DDR2 SDRAM. Here, a memory controller is coupled to two dual in-line memory modules (DIMMs). The DIMMs have a 2R/1R configuration, that is, the first module has two ranks of memory devices, and the second module has one rank. The ODT pin has been set such that the termination impedance is either in ON state with a termination impedance of 20Ω or in OFF state (denoted by ∞, i.e. essentially infinite termination impedance or unterminated). DIMM 2 has no second rank memory device (N/A).

The top row of FIG. 5 illustrates the selected termination impedances for a write command to Rank 1 of DIMM 1. The controller, which transmits write data to the modules, is unterminated. Shaded cells indicate the active DIMM/rank. Whenever a DIMM/rank is in active state, the ODT termination is set to OFF (∞). Inactive DIMM/rank is either in an OFF state (∞) or an ON state (termination impedance of 20Ω) so as to minimize any signal reflection.

### BRIEF DESCRIPTION OF THE DRAWINGS

FIG. 1 illustrates a prior art memory system with motherboard termination.

FIG. 2 illustrates a prior art memory system with on-die termination (ODT).

FIG. 3 illustrates a prior art ODT circuit.

FIG. 4 illustrates a prior art control scheme for ODT.

FIG. 5 illustrates the operation of a prior art memory system having ODT.

FIG. 6 illustrates an embodiment of a memory system according to some of the inventive principles of this patent disclosure.

FIG. 7 illustrates an embodiment of a memory agent according to some of the inventive principles of this patent disclosure.

FIG. 8 illustrates the operation of another embodiment of a memory system according to some of the inventive principles of this patent disclosure.

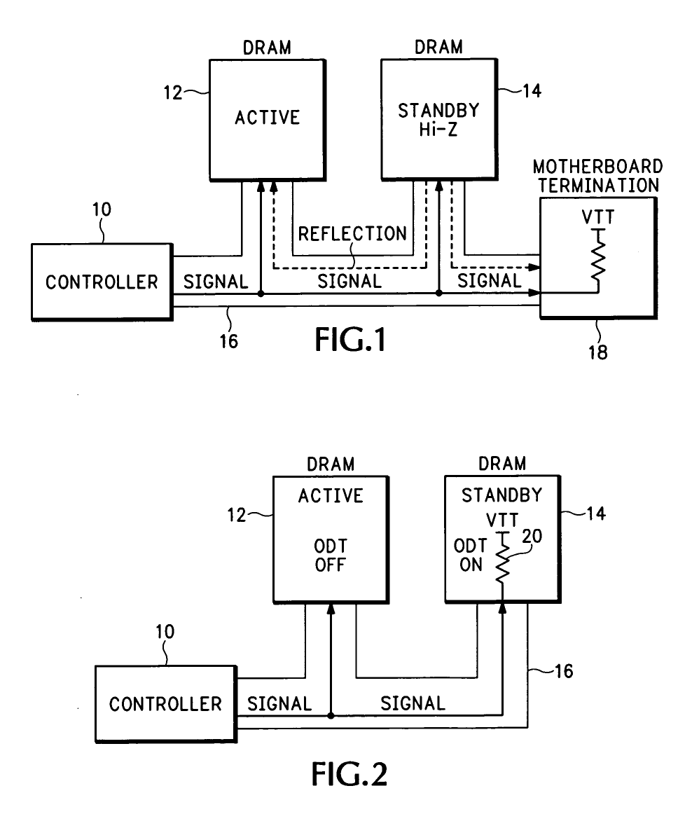

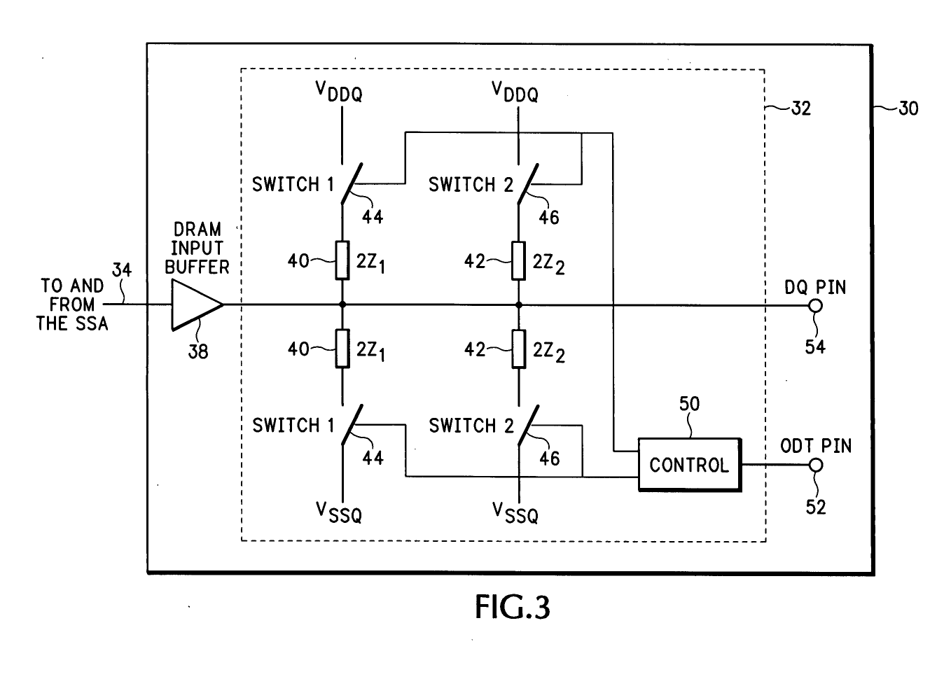

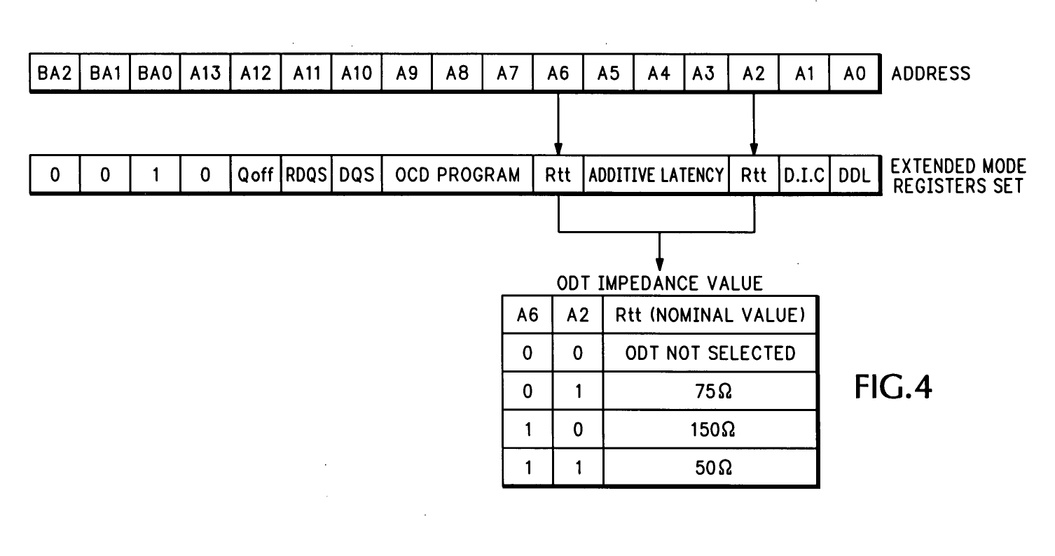

### DETAILED DESCRIPTION

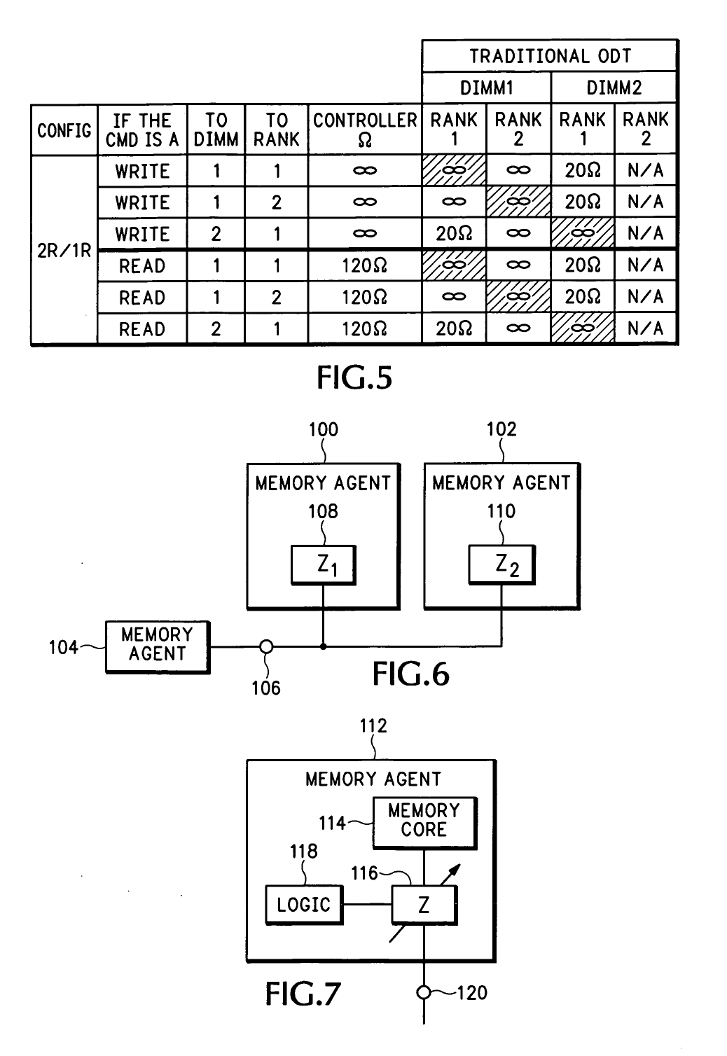

FIG. 6 illustrates an embodiment of a memory system according to some of the inventive principles of this patent disclosure. First and second memory agents 100,102 are coupled to a third memory agent 104 by a transmission line 106. The transmission line may be simultaneously terminated with a first impedance 108 at the first memory agent and a second, substantially different impedance 110 at the second memory agent. For example, during a write operation, the third memory agent may need to transmit data to the first memory agent. During this operation, the first memory is active and the second memory agent is inactive. The third memory agent transmits a signal which propagates to both memory agents over the transmission line. The termination impedances may be chosen so that more signal power is received at the first memory agent than the second memory agent. Preferably, the value of the first impedance Z₁ matches the transmission line so that power transfer to the first agent is maximized, and the value of the second impedance Z₂ is set to an appropriate low value so the signal is reflected and power transfer to the second agent is minimized.

In one embodiment, the transmission impedances Z₁ and Z₂ may be selected dynamically between changes in the active/inactive state of the memory agents, the type of command (read/write), etc. For example, if the write operation to the first memory agent 100 as described above is followed by a write to the second memory agent, the values of Z₁ and Z₂ may be switched between the back-to-back write operations so that the signal is reflected by Z₁ at the first agent (which is now inactive), and absorbed by Z₂ at the second agent (which is now active). In an embodiment having multiple ranks of memory devices, the transmission impedances for different ranks may also be selected dynamically.

FIG. 7 illustrates an embodiment of a memory agent according to some of the inventive principles of this patent disclosure. The memory agent 112 includes a memory core 114, a terminator 116 having at least two finite termination values, and logic 118 to dynamically select the termination values that may be presented to a transmission line 120. In one embodiment, the memory agent may be a memory device having the core, the terminator and the logic fabricated on a single semiconductor die. In another embodiment, the memory agent may be a memory module where the memory core is located on a memory device mounted on the module.

The selected termination value may be changed dynamically depending on the active/inactive state of the memory agent, the type of command (read/write), etc. In an embodiment having multiple ranks of memory devices, the transmission impedances for different ranks may also be selected dynamically.

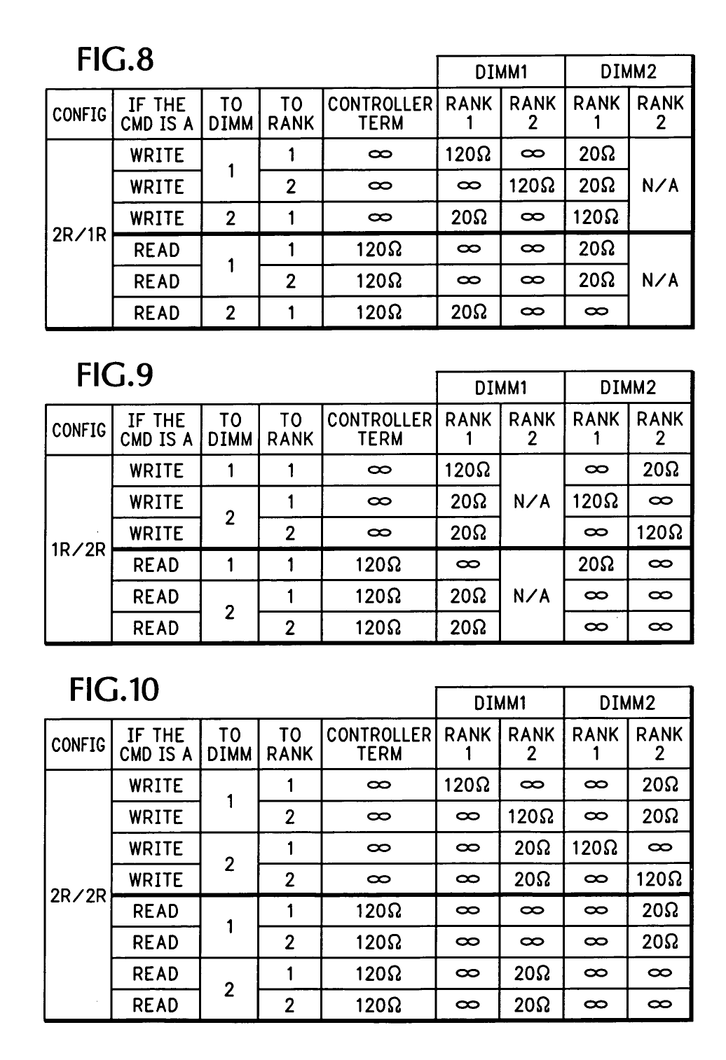

FIG. 8 illustrates the operation of another embodiment of a memory system according to some of the inventive principles of this patent disclosure. In this example, one memory agent is a memory controller, and two agents are modules, specifically, dual in-line memory modules (DIMMs). The DIMMs have a 2R/1R configuration, that is, the first module has two ranks of memory devices, and the second module has one rank. The memory controller and modules are connected by a memory channel having a bus structure and signaling similar to DDR2, but with dynamic termination according to some of the inventive principles of this patent disclosure. For this example, the terminators are assumed to be on-die in the memory devices, and the termination impedances may be resistances of 20Ω and 120Ω for a system operating at 1333 Mts.

The top row of FIG. 8 illustrates the selected termination impedances for a write command to Rank 1 of DIMM 1. Shaded cells in FIG. 8 indicate the active DIMM/rank. The controller, which transmits write data to the modules, is unterminated as indicated by the ∞ symbol (essentially infinite impedance or “off” state). A termination impedance of 120Ω is selected for the active device which is the Rank 1 memory device on DIMM 1. The Rank 2 memory device on DIMM 1 is inactive and unterminated. A termination impedance of 20Ω is selected for the inactive Rank 1 memory device on DIMM 2. DIMM 2 has no second rank memory device (N/A). This selection of termination impedances may cause more signal power to be transmitted to the active device than any of the inactive devices. Depending on the implementation details of the memory channel transmission lines, on-die termination circuits, module connectors, operating speed, etc., the termination impedance for an active device (120Ω ) may be matched to the transmission line to maximize power transfer to the active device, while the termination impedance for an inactive device (20Ω) may be chosen to reflect most of the power and minimize signal transfer to the inactive device.

The next two rows of FIG. 8 illustrate the selection of termination impedances for write commands to Rank 2 of DIMM 1, and Rank 1 of DIMM 2. The bottom three rows illustrate the selection of termination impedances for read commands for all three combinations of active DIMMs and ranks of memory devices.

As compared to the prior art system illustrated in FIG. 5, the embodiment of FIG. 8 may enable a transmission line to be simultaneously terminated with two different impedances at different memory agents. Moreover, some of the inventive principles of this patent disclosure may enable termination impedances to be varied dynamically between read/write, active/inactive states, whereas prior art systems could only enable or disable termination, not change the termination value except, e.g., during the process of changing an extended mode register.

FIG. 9 illustrates the operation of another embodiment of a memory system according to some of the inventive principles of this patent disclosure. In the example of FIG. 9, the system is similar to the embodiment of FIG. 8, but with a 1R/2R configuration; that is, the first module has one rank of memory devices, and the second module has two ranks. FIGS. 10 and 11 illustrate the operation of two more embodiments of memory system according to some of the inventive principles of this patent disclosure, this time with 2R/2R and 1R/1R configurations, respectively.

The embodiments described herein may be modified in arrangement and detail without departing from some of the inventive principles. For example, embodiments have been described having specific numbers of modules, memory devices, ranks, operating speeds, termination impedances and resistances, etc., but the inventive principles are not limited to these details. Terminators are described as having different termination values, but they need not necessarily be switched between discrete values. Logic may be implemented in hardware, software, or a combination of both. As a further example, memory modules and memory controllers may be implemented as separate components, or they may be fabricated on a common printed circuit board. As yet another example, some of the embodiments describe memory write operations from a memory controller to a memory module, but some of the inventive principles may also be applied to module-to-module transfers, controller-to-memory device transfers, and other configurations. Accordingly, such variations are considered to fall within the scope of the following claims.

1. A memory agent comprising:
a memory core;
a terminator having at least two termination values; and
logic to dynamically select the termination values.

2. The memory agent of claim 1 where the memory core and terminator are fabricated on a semiconductor die.

3. The memory agent of claim 2 where the logic is fabricated on the semiconductor die.

4. The memory agent of claim 1 where the memory agent comprises a memory module.

5. The memory agent of claim 1 where the memory agent comprises a memory device.

6. The memory agent of claim 1 where the selected termination value may be changed in response to a state of the memory agent.

7. The memory agent of claim 6 where the memory agent may operate in states including an active state and an inactive state.

8. The memory agent of claim 7 where a first termination value is selected in the active state and a second termination value is selected in the inactive state.

9. The memory agent of claim 1 further comprising:
a second memory core;
a second terminator having at least two termination values; and
second logic to dynamically select the termination values of the second terminator.

10. A memory system comprising:
a first memory agent;
a second memory agent;
a third memory agent; and
a transmission line to couple the first and second memory agents to the third memory agent;
where the transmission line may be simultaneously terminated with a first impedance at the first memory agent and a second, substantially different impedance at the second memory agent.

11. The system of claim 10 where the first impedance substantially matches the transmission line.

12. The system of claim 10 where the first and second impedances cause substantially more signal transfer to an active memory agent than an inactive agent.

13. The system of claim 10 where the first and second impedances substantially maximize signal transfer to the first memory agent and substantially minimize signal transfer to the second memory agent.

14. The system of claim 10 where the first memory agent may terminate the transmission line with the first termination impedance in an active state and the second termination impedance in an inactive state.

15. The system of claim 10 where:
the first memory agent includes first rank and second rank memory devices coupled to the transmission line;
the first rank memory device may be terminated with the first impedance when the first memory agent is active, and the first rank memory device is active; and
the second rank memory device may be unterminated when the first memory agent is active, and the second rank memory device is inactive.

16. The system of claim 15 where:
the second memory agent includes third rank and fourth rank memory devices coupled to the transmission line;
the third rank memory device may be unterminated when the first memory agent is active and the second memory agent is inactive; and
the fourth rank memory device may be terminated with the second impedance when the first memory agent is active and the second memory agent is inactive.

17. A method comprising dynamically varying the termination impedance of a memory agent.

18. The method of claim 17 where the termination impedance of the memory agent is substantially higher in an active state than an inactive state.

19. The method of claim 17 where:
the memory agent includes first and second rank memory devices coupled to a transmission line; and
the method further comprises terminating the first rank memory device with a first impedance and leaving the second rank memory device unterminated when the first rank memory device is active.

20. The method of claim 17 further comprising dynamically varying the relative termination impedances of two or more memory agents coupled to a transmission line.

21. The method of claim 20 where the termination impedances may be varied such that substantially more signal power is power is transferred to an active memory agent than an inactive agent.

22. The method of claim 21 where the termination impedances may be varied such that substantially maximum signal power is transferred to the active memory agent and substantially minimum signal power is transferred to the inactive agent.
